(19) United States
(12) Patent Application Publication
(10) Pub. No.: US 2026/0223648 A1
(43) Pub. Date: Jul. 30, 2026

(54) METHOD AND SYSTEM FOR PRODUCING MICROELECTRONIC COMPONENTS WITH A LAYER STRUCTURE

(71) Applicant: 3D-Micromac AG, Chemnitz (DE)

(72) Inventors: Torsten Leichsenring, Wildenfels (DE); Sven Albert, Penig (DE); Maurice Clair, Chemnitz (DE); Michael Grimm, Chemnitz (DE); Bernd Keiper, Burgstädt (DE)

(73) Assignee: 3D-Micromac AG, Chemnitz (DE)

(21) Appl. No.: 19/159,134

(22) PCT Filed: Feb. 12, 2024
(86) PCT No.: PCT/EP2024/053491

§ 371 Date: Aug. 22, 2025

(30) Foreign Application Priority Data
Feb. 22, 2023 (DE) 10 2023 201 553.6

(51) Int. Cl. H10P 95/00; B23K 26/067; B23K 26/08; B23K 26/53; B23K 101/40

(52) U.S. Cl. CPC H10P 95/11; B23K 26/067; B23K 26/0853; B23K 26/53; B23K 2101/40

(57) ABSTRACT

A method for producing microelectronic components including a carrier and at least one microelectronic functional layer system applied to the carrier includes: forming a functional layer system on a front side of a growth substrate; arranging a layer-shaped carrier on a side of the functional layer system opposite to the growth substrate to form an arrangement including the carrier, the functional layer system, and the growth substrate; radiating in laser radiation from a rear side of the growth substrate through the growth substrate such that the laser radiation, in a boundary area between the growth substrate and the functional layer system, weakens or destroys a connection between the growth substrate and the functional layer system in the boundary area in locally bounded areas or comprehensively; and transferring the functional layer system or parts thereof onto the carrier to form a microelectronic component.

### CROSS-REFERENCE TO RELATED APPLICATIONS

This application is a US national stage filing under 35 U.S.C. § 371 of International Application No. PCT/EP2024/053491, filed Feb. 12, 2024, which claims priority to German Patent Application No. 10 2023 201 553.6, filed Feb. 22, 2023, each of which is incorporated herein by reference in its entirety.

### TECHNICAL FIELD

This disclosure relates to a method for producing microelectronic components and a system that performs the method. Furthermore, the disclosure relates to the use of a device for direct laser interference patterning to irradiate a boundary area between a growth substrate and a functional layer system to weaken or destroy a connection between the growth substrate and the functional layer system in a laser lift-off method or a LIFT method.

### BACKGROUND

In the production of microelectronic components, such as optoelectronic components, there is often the task of separating a layer stack consisting of a plurality of layers between two defined layers, to thus obtain two individual layer stacks. For example, light-emitting diodes (LEDs) are presently often produced in that on a sapphire wafer used as a growth substrate, p-doped and n-doped semiconductor layers are formed from gallium nitride (GaN) by epitaxial growth. Those layers each have a thickness of a few microns, the total thickness of the various GaN layers can be, for example, less than 10 μm. Before the further processing, the GaN layers can be structured, for example, by laser processing, to produce individual components or prepare for their production. A thin, generally metallic connecting layer is applied to the GaN layer stack, for example, by vapor deposition. The growth substrate having the GaN layer stack located thereon is connected to a layered planar carrier with the aid of the connecting layer. The planar connection between the growth substrate and the GaN stack is later detached. The GaN stack is thus transferred to the carrier. The carrier having the GaN stack carried thereon is used as the basis for the production of the microelectronic components.

The separation of the functional layer stack including the carrier and the GaN layer stack from the growth substrate is usually carried out presently with the aid of the so-called laser lift-off method. In that case, a buffer layer, which is located in the boundary area between the growth substrate and the GaN layers, is destroyed or removed by laser irradiation. The irradiation takes place from the rear side of the growth substrate and through it, wherein the laser beam is focused on the buffer layer or the boundary area. The growth substrate can then be separated from the other layers by external force action.

Such a method is described, for example, in the article “Laser-Lift-Off: Geringere Bauhöhen in der Mikroelektronik durch Substrat-Transfer” [laser lift-off: lower structural heights in microelectronics by substrate transfer] by R. Delmdahl in: Photonik 2(2013 ), pages 54 to 56. Accordingly, fundamentally two excimer laser processing strategies are used for rapid and reliable layer separation, which differ due to the geometry of the homogeneous laser field. The laser lift-off is either carried out by sweeping by a linear beam of suitable length as a line scan or by step-by-step placement of rectangular laser processing fields adjacent to one another.

DE 10 2017 205 635 A1 describes further laser lift-off methods and devices. To irradiate relatively large separating areas by laser within a short processing time if needed, it is provided in some embodiments that a laser beam having a line profile is irradiated and a relative movement takes place between laser beam and workpiece transversely to the longitudinal axis of the line profile. Step and repeat methods are also mentioned.

Laser lift-off methods are described in U.S. Pat. No. 10,297,503 B2, in which a laser beam, after passing through a beam former, passes a diffractive optical element (DOE) or a beam splitter mask having a plurality of passage apertures and is thus decomposed into a plurality of partial beams of smaller beam cross section offset laterally in relation to one another, which are incident on the layer to be irradiated in a pre-determinable arrangement having mutual spacing.

So-called LIFT methods are also known, wherein the abbreviation LIFT stands for laser-induced forward transfer. In that case, there is a defined small distance at the beginning of the method between the growth substrate having the GaN layer stack located thereon and the layer-shaped planar carrier. The connection between growth substrate and layer stack is then damaged in irradiated segments of the GaN layer stack by local laser irradiation. The GaN is then split into Ga and nitrogen, wherein the resulting gas pressure detaches the planar segments from the growth substrate and accelerates them in the direction of the layer-shaped planar carrier. After the processing step, the locally laser-irradiated segments are located on the layer-shaped planar carrier and are no longer connected to the growth substrate.

Presently, comparatively cost-intensive UV lasers having high pulse energy and complex optics and therefore relatively significant wear of the mentioned components are used to carry out the method. Destruction can sometimes additionally occur in the area of the GaN layer stack due to the uniformly very high laser fluence in the entire processing area. The function of the affected microelectronic component could thus be impaired and therefore the yield of the LLO or LIFT process could be reduced accordingly.

It could therefore be helpful to provide a method and a system of the type in question so that it is implementable relatively cost-effectively and in which the separating step, by which the growth substrate used as a temporary substrate is separated from the other layers, can be carried out more reliably than previously.

### SUMMARY

Disclosed herein is:
A method for producing microelectronic components including a carrier and at least one microelectronic functional layer system applied to the carrier, the method including: forming a functional layer system on a front side of a growth substrate; arranging a layer-shaped carrier on a side of the functional layer system opposite to the growth substrate to form an arrangement including the carrier, the functional layer system, and the growth substrate; radiating in laser radiation from a rear side of the growth substrate through the growth substrate such that the laser radiation, in a boundary area between the growth substrate and the functional layer system, weakens or destroys a connection between the growth substrate and the functional layer system in the boundary area in locally bounded areas or comprehensively; transferring the functional layer system or parts thereof onto the carrier to form a microelectronic component, wherein the boundary area is irradiated by direct laser interference patterning (DLIP), wherein a laser beam emitted by a primary laser radiation source is split into at least two partial beams and the partial beams are guided so that at least two partial beams coherent with one another extend through the growth substrate and a spatial intensity pattern results in a superposition area of the coherent laser beams including radiation micro-zones having constructive interference and relatively high power density of the laser radiation adjacent to areas of destructive interference and low power density of the laser radiation relative to the radiation micro-zones, wherein micro-zones damaged by the laser radiation of the radiation micro-zones are generated in the boundary area, which are located in an arrangement with lateral distances to one another.

A system that produces microelectronic components including a carrier and at least one microelectronic functional layer system applied to the carrier, the system including: a workpiece carrier for accommodating an arrangement having a growth substrate, a functional layer system formed on a front side of the growth substrate, and a carrier, arranged on a side of the functional layer system opposite to the growth substrate; a laser processing station for radiating laser radiation from a rear side of the growth substrate through the growth substrate such that the laser radiation is guided in a boundary area between the growth substrate and the functional layer system and a connection between the growth substrate and the functional layer system is weakened or destroyed in the boundary area, wherein the laser processing station includes a laser-optical arrangement for laser patterning, in which a laser beam emitted by a primary laser radiation source can be split into at least two partial beams and the partial beams can be guided so that at least two partial beams coherent with one another extend through the growth substrate and a spatial intensity pattern is generated in a superposition area of the coherent partial beams including radiation micro-zones having constructive interference and relatively high power density of the laser radiation adjacent to areas of destructive interference and low power density of the laser radiation relative to the radiation micro-zones, wherein micro-zones damaged by the laser radiation of the radiation micro-zones can be generated in the boundary area, which are located in an arrangement having lateral distances to one another.

A device for direct laser interference patterning (DLIP) that irradiates a boundary area between a growth substrate and a functional layer system to weaken or destroy a connection between the growth substrate and the functional layer system in a laser lift-off method or a LIFT method.

### BRIEF DESCRIPTION OF THE DRAWINGS

Further advantages are evident from the description of exemplary embodiments explained hereinafter on the basis of the figures.

FIG. 1 shows a schematic section through a workpiece in the form of a layer composite having an exemplary layer structure during the laser processing by direct laser interference patterning.

FIG. 2 shows an example of a laser processing station configured to use direct laser interference patterning to weaken a layer within a layer structure in the context of a laser lift-off method and prepare it for separation.

FIGS. 3A and 3B show microscopic pictures of an overview (FIG. 3A) and a detail (FIG. 3B) of a regular pattern of micro-zones, generated by the use of DLIP, in the boundary area of an irradiated workpiece in the case of irradiation through a polished rear side of a growth substrate.

FIG. 4 shows an example of a regular micro-grid arrangement of micro-zones, which were generated in two successively performed processing steps using different settings of a DLIP device.

FIG. 5 shows an example of the distribution of micro-zones after a DLIP patterning through an unpolished rear side of a growth substrate.

### DETAILED DESCRIPTION

The method is used to produce microelectronic components, which comprise a carrier and at least one microelectronic functional layer system applied to the carrier. In the method, a functional layer system is formed on a front side of a growth substrate. A layer-shaped carrier is then arranged on the side of the functional layer system facing away from the growth substrate. An arrangement is thus formed which comprises the carrier, the functional layer system, and the growth substrate.

The carrier can be arranged in planar contact with the functional layer system and connected thereto so that a workpiece in the form of a layer composite is formed, which comprises the carrier, the functional layer system, and the growth substrate in the form of a layer stack. This is the case, for example, in LLO methods. The arrangement can also be made so that a small distance remains between the free surface of the functional layer system and the carrier. This is the case, for example, in LIFT methods.

The workpiece (layer composite having carrier, functional layer system, and growth substrate) or the arrangement (functional layer system on growth substrate and the carrier separated therefrom) can then be fastened on a workpiece carrier such that the rear side of the growth substrate opposite to the front side is accessible for subsequent laser processing. In the laser processing, laser radiation is radiated from the rear side of the growth substrate through the growth substrate such that the laser radiation weakens or destroys an initially still existing connection between the growth substrate and the functional layer system in a boundary area between the growth substrate and the functional layer system in a locally bounded or comprehensive manner in the boundary area.

A transfer of the functional layer system or parts thereof to the carrier to form the microelectronic component thus becomes possible. In the LLO method, for this purpose a functional layer stack which comprises the carrier and the functional layer system applied thereon is separated from the growth substrate. A substrate transfer of the complete functional layer system from the growth substrate to the carrier thus takes place. In the LIFT method, the transfer can take place selectively such that only selected parts or segments of the functional layer system are transferred over a short flight path onto the carrier.

Economic manufacturing of semiconductor structures on ever larger and more sensitive carriers is above all possible by way of this method.

In one example, the boundary area is irradiated by direct laser interference patterning (DLIP). A laser beam emitted by a primary laser radiation source is split into at least two partial beams and the partial beams are guided so that at least two partial beams coherent with one another extend through the growth substrate and a spatial intensity pattern arises in a superposition area of the coherent laser beams, which comprises radiation micro-zones having constructive interference and relatively high power density of the laser radiation adjacent to areas of destructive interference and lower power density of the laser radiation relative to the radiation micro-zones. Damaged micro-zones are thus generated in the boundary area by the laser radiation of the radiation micro-zones, which are located in an arrangement having lateral distances to one another.

The boundary area is thus irradiated with the aid of a method variant of direct laser interference patterning (DLIP). Direct laser interference patterning (DLIP) is a laser-based technology which uses the physical principle of the interference of high-intensity coherent laser beams to produce functional periodic microstructures. A corresponding laser processing facility comprises a laser-optical arrangement for laser patterning, in which a laser beam emitted by a primary laser radiation source is split into at least two partial beams and these are guided so that at least two partial beams interfering with one another meet at an area to be processed. A spatial intensity pattern is generated in the area of the superimposed coherent laser beams. The areas having constructive interference form the radiation micro-zones, which cause the occurrence of the micro-zones in the boundary area material, while the areas of destructive interference (or extinguishing) result in the intermediate areas which are not irradiated or are only irradiated weakly between adjacent micro-zones. The beam diameter of the partial beams does not have to be focused or does not have to be focused to a minimum beam diameter, in contrast to other processing methods, such as laser inscription. A significantly larger area can thus be processed per laser pulse.

If two coherent laser beams are superimposed, a line pattern results. Three or four laser beams are in some instances brought to interference, so that essentially punctiform micro-zones result in the irradiated area. The micro-zones then have distances from one another in three or more different lateral directions.

Commercially available laser processing systems for direct laser interference patterning can be used within the scope of methods according to this disclosure. For example, a laser-optical arrangement according to EP 3 466 598 A1 can be used. The disclosure of this document is incorporated herein by reference.

One solution to the problem can also be described such that the laser radiation of a primary laser radiation source is prepared or irradiated for the irradiation of the laser radiation without the use of a beam splitter mask such that radiation micro-zones of high power density of the laser radiation are generated in the boundary area such that micro-zones damaged by the laser radiation of the radiation micro-zones are generated in the boundary area, which are located in an arrangement having relatively small average lateral distances to one another. These distances can be in the single-digit or low double-digit micrometer range.

A fine pattern of relatively small, locally bounded zones is generated in the material of the boundary area, in which the power density of the laser radiation is sufficient to damage or weaken the boundary area or the material in the boundary area so that a separation along the boundary area or a detachment from the growth substrate becomes possible. The term “micro-zone” expresses here that the lateral dimensions of the zones of the boundary area, which were damaged and/or destroyed due to the locally elevated power density, are in the single-digit micrometer range or less in at least one lateral direction. The average lateral distances between directly adjacent micro-zones are also very small and are in the single-digit or low double-digit micrometer range. The term “distance” refers here to the minimum center distance between directly adjacent micro-zones, thus the center distance in the direction in which the center distance assumes its smallest value.

In a radiation micro-zone, the intensity or the power density of the laser radiation is increased by the beam preparation in comparison to the surroundings of the radiation micro-zone such that the power density is sufficient to initiate the procedures required for weakening the material in the boundary area and to generate the weakened micro-zones there. In comparison to the radiation micro-zones, the power density in the areas between directly adjacent radiation micro-zones is less by orders of magnitude, so that the laser radiation does not directly result there in weakening or destruction within the boundary area. However, adjacent micro-zones are sufficiently close to one another that nonetheless weakening is generated in the entire part of the boundary area covered with micro-zones starting from the areas of the micro-zones damaged directly by laser radiation and the components to be separated from one another can be reliably separated.

During the transfer of the functional layer system or parts thereof onto the carrier to form the microelectronic component, a separation of the components to be separated from one another therefore takes place along the boundary area which is locally weakened or destroyed in the area of the micro-zones, wherein the separation, starting from the micro-zones, also extends through the intermediate areas which are adjacent to the micro-zones and are not directly weakened.

It has been shown that with such a fine distribution of very small micro-zones, a sufficient weakening of the functional layer system can be achieved in the boundary area without negatively affecting the adjoining layer materials to the extent as is sometimes the case with significantly larger weakening zones. This type of laser processing is therefore particularly gentle to the areas adjoining the boundary area.

Many micro-zones, e.g., more than 100 or more than 500 or more than 1000 or more than 2000, are in some instances generated simultaneously in one processing step, so that in spite of the small dimensions of the micro-zones and the intermediate distances, larger areas of the boundary area can be weakened in a relatively short time and thus prepared for the separation.

If DLIP technology is used, it is possible to prepare the laser radiation provided by the primary laser radiation source without the use of a beam splitter mask provided with many passage openings such that the fine distribution of micro-zones results. This contributes to the power provided by the primary laser radiation source being able to be used with particularly high efficiency for weakening in the boundary area. If the use of a beam splitter mask is dispensed with, losses which arise in conventional systems using a beam splitter mask due to this type of geometrical beam splitting can be avoided. In other words: practically no laser power is discarded uselessly, but rather a high proportion of the laser energy provided by the primary laser radiation source can be used for weakening the layer system in the boundary area. The energy of the laser radiation is substantially retained in this case, and is only locally redistributed. Therefore, no process-related additional weakening of the laser radiation occurs, which goes beyond losses of real components, such as reflection or scattering at boundary surfaces.

Due to the high efficiency in the utilization of the laser power provided by the primary laser radiation source, it is not necessary in the method to make use of lasers of high pulse power as the primary laser radiation source. In some embodiments, a suitable solid-state laser is therefore used as the primary laser radiation source, which generates laser radiation from the ultraviolet range of the electromagnetic spectrum (UV solid-state laser), in particular at wavelengths of less than 400 nm. The wavelength range in which sapphire (as a typical material for the growth substrate) is substantially transparent and the GaN layer material sufficiently absorbs the radiation is particularly useful, thus, for example, in the range between 160 nm and 400 nm.

Commercially available short or ultrashort pulse lasers can be used, for example, having pulse durations of a few tens of femtoseconds to a few hundreds of nanoseconds. For example, diode-pumped IR lasers having Nd:YAG, Yb:YAG, Nd:YVO4, or Nd:YLF as the laser medium can be used as the primary laser radiation source, the radiation of which is converted via a frequency conversion, for example, frequency tripling to wavelengths in the UV range, so that wavelengths in the range around 350 nm are available. Laser wavelengths in the lower UV wavelength range around 266 nm can be generated via a frequency quadrupling. These are also suitable for the method, but are not preferably used because of the comparatively shorter lifetime of the crystals for the frequency quadrupling and because of the higher wear. Wavelengths around 350 nm are therefore presently used in some instances, among other things because the photon energy is sufficiently high for the LLO and LIFT applications considered here.

The most favorable dimensions of the micro-zones and the distances can vary from application to application. Very good results can be achieved in most cases in that a lateral extension of the micro-zones in at least one lateral direction is approximately 0.5 μm to 3 μm. Alternatively or additionally, the mean lateral distance between directly adjacent micro-zones can be approximately 1 μm to approximately 15 μm.

In general, it is favorable if punctiform micro-zones are generated. The term “punctiform” means here that the individual micro-zones essentially have a round shape. This means in particular that diameter variations in different diametric directions are at most 20%, in particular at most 10% of the largest diameter.

Alternatively, the micro-zones can also have other shapes, e.g., oval, approximately square, approximately rectangular, or linear. It is therefore possible to adapt the shape of the micro-zones better to the application, for example, by using a shape (and size) of the micro-zones which corresponds to the shape (and size) of micro-LEDs to be transferred.

Sometimes, only two superimposed partial beams are used, so that an interference pattern having linear radiation micro-zones results due to two-beam interference. The use of linear micro-zones permits a substantially uniform irradiation of the entire wafer if a suitable pulse interval is set. The lateral extension in the width direction can be in the above-mentioned range (approximately 0.5 μm to approximately 3 μm), the length can be significantly greater, for example, several hundred micrometers or approximately 1 mm or more.

In the DLIP method, the micro-zones can have a periodic micro-grid arrangement under certain boundary conditions (for example, low-interference coupling into the growth substrate) because of the system, which is conducive to generate conditions distributed as uniformly as possible over the entire irradiated boundary area.

There are numerous possibilities within the scope of the method with respect to the spatial distributions of the micro-zones that can be generated in the boundary area. It can be sufficient to generate all micro-zones of an irradiated area essentially according to a uniform grid. If necessary, combinations of two or more different grid arrangements can also be generated in succession. In one embodiment, in a surface area of the boundary layer, micro-zones are generated in at least two processing steps performed in chronological succession, wherein in a first processing step, a first micro-grid arrangement of first micro-zones is generated, and in a following second processing step, second micro-zones, which are distributed according to a second micro-grid arrangement, are generated in intermediate areas between the first micro-zones.

It is also possible in some cases that a more or less statistical distribution of micro-zones is generated in the boundary area, the lateral distances and lateral dimensions of which vary statistically in certain dimension ranges, in particular within the dimension ranges already mentioned herein.

This disclosure also relates to the use of a system for direct laser interference patterning (DLIP) for irradiating a boundary area between a growth substrate and a functional layer system to weaken or destroy a connection between the growth substrate and the functional layer system in a laser lift-off method or a LIFT method.

The use of suitable variants of direct laser interference patterning (DLIP) in the context of laser lift-off methods or LIFT methods offers advantages not only in regard to the targeted weakening in the boundary area, but rather can also contribute at another point to reducing the overall cost of production processes which work using laser lift-off operations and/or LIFT operations.

In many process variants possible within the scope of this disclosure, growth substrates can be used which are separated by a mechanical separation process from a larger substrate material block. For example, sapphire wafers usable as growth substrates can presently in general be cut using a saw from a larger sapphire block. The surfaces thus available can be relatively rough. This can in turn result in problems in the coupling of the laser radiation into the growth substrate with conventional laser processing methods. To avoid such problems, it has been proposed, for example, in DE 10 2017 205 635 A1 before the irradiation of the laser beam that a liquid layer made of a liquid transparent to the laser radiation be brought into contact with the (rough) rear side of the growth substrate and the laser beam be irradiated through the liquid layer. The efficiency in the coupling in of the laser beam could thus also be substantially improved with rough rear sides. Alternatively, the rear side can also be processed by lapping and/or polishing to prepare for the laser processing, to create a sufficiently smooth coupling surface.

We have now shown that such complex and costly additional measures can be omitted in the preparation for laser processing if suitable variants of direct laser interference patterning are used to irradiate the boundary area. With roughness of the coupling surface which is not excessively high, essentially only the character of the distribution of the micro-zones changes. If the rear side of the growth substrate used as the coupling surface is polished or smoothed in another way (for example, lapping and polishing) or provided with an immersion layer, regular lateral distributions of micro-zones having well definable dimensions can be generated. In contrast, if coupling takes place via a non-polished coupling surface, statistically distributed micro-zones having a broader dimension distribution and distance distribution occur more.

This method variant for generating micro-zones insofar appears relatively insensitive to problems induced by surface roughness. According to one refinement, a growth substrate can therefore be used which, on the rear side, has a surface roughness having an average roughness value Ra of greater than 0.1 μm, wherein the average roughness value is in some instances 0.5 μm to 1 μm. A wafer separated from a material block by sawing can therefore be used as a growth substrate and the laser radiation can be radiated onto the rear side generated by sawing without an interposed polishing step and in some applications also without the otherwise typical lapping process. A costly polishing step can therefore be omitted, due to which the production process can be made significantly more cost-effective.

This disclosure also relates to a system for producing microelectronic components, which comprise a carrier and at least one microelectronic functional layer system applied to the carrier. Among other things, LLO methods and LIFT methods can be performed using the system, wherein a device for direct laser interference patterning (DLIP) is used to irradiate a boundary area between a growth substrate and a functional layer system to weaken or destroy a connection between the growth substrate and the functional layer system in a laser lift-off method or a LIFT method.

Various aspects of our methods and systems for producing microelectronic components using a laser lift-off method and/or a LIFT method are described hereinafter on the basis of exemplary embodiments. The microelectronic components resulting as products of the method comprise a typically relatively thin planar carrier and at least one microelectronic functional layer system applied to the carrier.

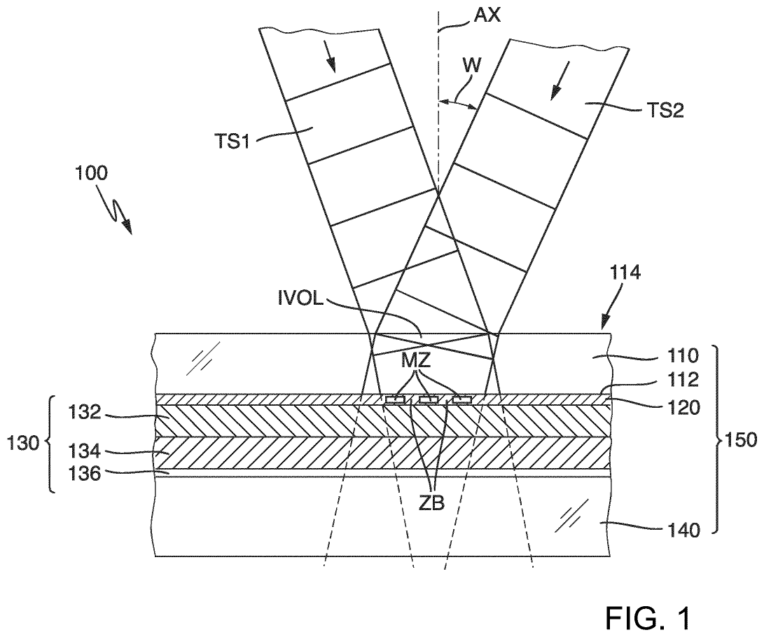

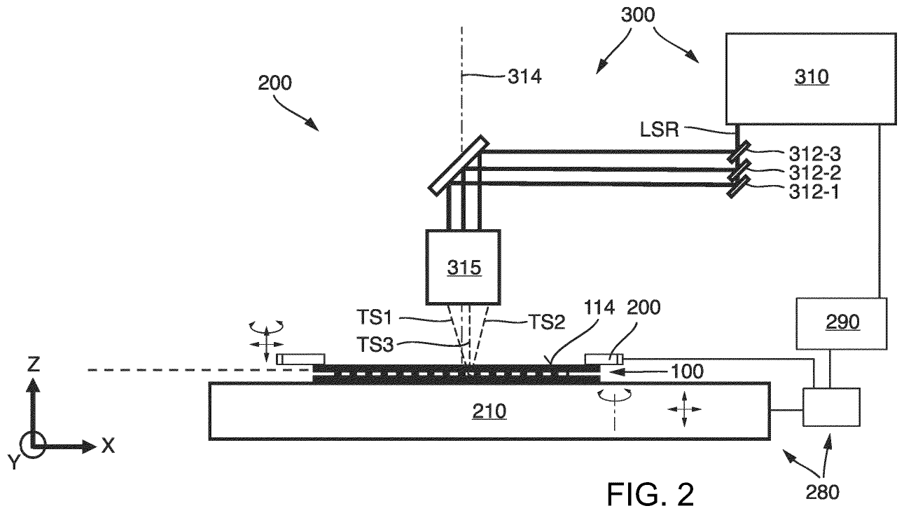

FIG. 1 shows a schematic section through a workpiece 100 in the form of a layer composite having an exemplary layer structure. The workpiece 100 is an intermediate product created in the course of the method, which is subjected, among other things, to laser beam processing. FIG. 2 shows an example of a laser processing station 200 provided for this purpose.

The workpiece 100 is a wafer composite for producing LEDs here, however, other layer materials and sequences and wafer materials are also possible. The process is described hereinafter on the basis of the production of power LEDs for the automotive sector, but the applicability of this disclosure is not restricted to this exemplary embodiment.

The workpiece 100 shown in FIGS. 1 and 2 comprises a growth substrate 110 in the form of a planar sapphire wafer. On the front side 112 of the growth substrate, which is processed flat with high precision, p-doped and n-doped semiconductor layers 132, 134 made of gallium nitride (GaN) are formed by epitaxial growth. A thin buffer layer 120 is formed in the boundary area to the growth substrate. The buffer layer can be a separate layer, for example, made of undoped GaN, or a thin partial layer of the first GaN layer. The GaN layers generally each have a thickness of a few microns, the total thickness of the layer system having the various GaN layers can be, for example, less than 10 μm.

Before the further processing, patterning of the GaN layers can be carried out, for example, by laser processing, to produce individual components or prepare for their production. These components are formed by parts or segments of the initially comprehensively grown layer system and in turn represent layer systems having identical layer structure, but having smaller lateral dimensions.

A connecting layer 136, which is generally a few micrometers thick, is applied to the GaN layer stack, for example, by vapor deposition. This connecting layer can consist, for example, of gold, platinum, chrome, or other metals. With the aid of this connecting layer, the growth substrate having the GaN layer stack located thereon is connected to a layer-shaped planar carrier 140. The carrier is formed in the example by a thin plate made of glass, but can also consist of another material, for example, a semiconductor material such as silicon. The connecting layer 136 and the adjoining GaN layers form, possibly with further layers, a functional layer system 130, which is essentially responsible for the functionality of the component to be produced and is carried in the finished component by the carrier or an associated section of the carrier 140. The layer composite having the carrier 140 and the functional layer system 130 is referred to here as the functional layer stack 150.

The sapphire wafers used as the growth substrates are generally cut using a saw out of a larger sapphire block (sapphire ingot). Surfaces of high roughness result due to the sawing. The rear side 114 of a growth substrate made of sapphire can have, for example, a mean surface roughness (Ra) of 1 μm or somewhat less.

In the example, the rear side has been smoothed by polishing to Ra approximately 0.3 nm, to avoid stronger scattering losses when the laser radiation is coupled in.

FIG. 2 schematically shows a laser processing station 200, which is configured as part of a system for producing microelectronic components for a laser lift-off (LLO). The system comprises a workpiece carrier 210 for accommodating the workpiece 100. The workpiece is accommodated on the workpiece carrier with the rear side 114 of the growth substrate 110 facing upward.

The laser processing station 200 comprises a workpiece movement system 280, which is configured to position a workpiece to be processed in a desired processing position of the laser processing station in reaction to movement signals of the control unit 290. In the configuration of FIG. 2, the workpiece movement system 280 comprises the workpiece carrier 210, which can be moved parallel to the (horizontal) x-y plane of the system coordinate system and in the vertical direction (parallel to the z direction) very accurately to a desired position and can be rotated around a vertical axis of rotation (PHI axis). Precisely actuatable electric direct drives are provided for this purpose in the example.

Furthermore, the movement system 280 comprises a second workpiece carrier 220 above the first workpiece carrier 210, which can also be moved in a controlled manner in arbitrary directions horizontally (parallel to the x-y plane) and vertically (parallel to the z direction) and can be rotated around a vertical axis. The two workpiece carriers can be positioned independently of one another. In LLO methods, the upper second workpiece carrier is not used. It is used in LIFT methods to hold the growth substrate at a distance above the lower workpiece carrier.

The laser processing station is used to radiate laser radiation through the growth substrate from the rear side 114 of the growth substrate 110 such that the laser radiation is guided in a flatly extended boundary area between the growth substrate 110 and the functional layer system 130 (cf. FIG. 1) and a connection between the growth substrate 110 and the functional layer system 130 is weakened or destroyed in the boundary area. The boundary area can be located, for example, in the buffer layer 120 or contain it.

One special feature is that the boundary area is irradiated by a method variant of direct laser interference patterning (DLIP). Direct laser interference patterning (DLIP) is a laser-based technology, which uses the physical principle of the interference of high-intensity coherent laser beams to produce functional periodic microstructures at surfaces. In contrast to conventional applications, DLIP is used here to weaken a thin layer (boundary area) arranged in the interior of the workpiece at a distance from its free surfaces.

The laser processing station comprises a laser-optical arrangement 300 for laser structuring. An untreated laser beam LSR emitted by a primary laser radiation source 310 is split by three physical beam splitters 312-1, 312-2, 312-3 into three coherent partial beams TS1, TS2, TS3. An ultrashort pulsed laser having a solid-state laser medium is used here as the primary laser radiation source 310, which emits in the ultraviolet range at a wavelength of approximately 355 nm.

The three partial beams are guided via a 45° deflection mirror 314 and a focusing optical unit 315 so that they interfere with one another in a three-dimensionally extended superposition area (interference volume IVOL, cf. FIG. 1). The focusing optical unit 315 can be formed by a single lens or by a lens system having multiple lenses. The three partial beams are arranged symmetrically to the center of the focusing optical unit or its optical axis 314 in the corner points of an equilateral triangle.

FIG. 1 schematically illustrates the situation with two coherent partial beams TS1, TS2. The partial beams each propagate in propagation directions which are aligned at an acute angle W to the optical axis AX of the focusing optical unit 315. They are each offset by 120° to one another in the azimuthal angle. The angle W is continuously adjustable.

The structure of the laser-optical arrangement 300 is to be understood solely as an example. There are commercially available DLIP systems which can be used for the purpose in the foreground here. Several examples of systems usable in principle are shown in EP 3 466 598 B1, EP 3 735 332 B1.

The interfering partial beams penetrate the transparent growth substrate 110 substantially free of absorption, and the laser radiation is first absorbed strongly upon incidence on the buffer layer 120 and changes the material there. A spatial intensity pattern is generated in a superposition area of the coherent laser beams (partial beams TS1, TS2, TS3). Relatively high laser power densities arise here in a locally bounded manner in the areas having constructive interference. Small-volume areas in which the laser power density is sufficient to weaken the material of the boundary area are referred to here as radiation micro-zones. Where these extend into the boundary area material, micro-zones MZ are formed in the boundary area material, in which the boundary area material is vaporized and/or destroyed or weakened in another manner. The microscopically small micro-zones MZ are present with a distance to one another in a regular micro-grid arrangement. In areas of destructive interference, intermediate areas ZB which are not irradiated or are only irradiated weakly remain between adjacent micro-zones.

Although the power density only has a directly weakening effect on the boundary area material (here GaN) in the area of the radiation micro-zone and causes the micro-zone there, a planar weakening is nonetheless achieved, because the material in the intermediate areas ZB between the processing points (micro-zones) is also detached due to the nitrogen pressure as a result of the decomposition of nitride.

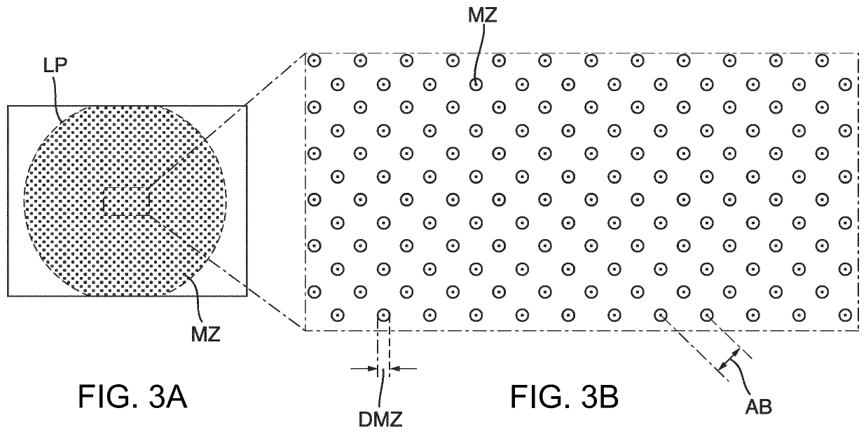

To illustrate the changes in the irradiated boundary area, FIGS. 3A and 3B show microscopic pictures of the structures in the boundary area of an irradiated workpiece during an experimental series. FIG. 3A shows substantially the complete, approximately circular surface (enclosed by the dashed line LP), which was irradiated by a single laser pulse, thus in principle the intersection surface between the planar boundary area and the interference volume. A transition area to an adjacent pulse can be seen at the right edge. FIG. 3B shows an enlarged detail from the central area of the circular processing area irradiated by a pulse.

It can be seen clearly that in the area of the interference volume, a regular structure of more or less circular micro-zones MZ was generated according to a rectangular grid. Several hundred micro-zones MZ distributed uniformly over the surface were generated simultaneously by a pulse in the approximately circular irradiated area. In accordance with the intensity distribution within the partial beams interfering with one another, the micro-zones MZ are more strongly pronounced in the central area than at the radial edge of the illuminated area LP. The mean diameter DMZ of the individual circular micro-zones was approximately 1.9 μm, corresponding to an area of a micro-zone of approximately 2.8 to 2.9 μm² . The smallest distance AB of a micro-zone to a directly adjacent micro-zone measured between the centers of the respective micro-zones was approximately 5.1 μm. The micro-zones are uniformly distributed within an area irradiated by a pulse, and, in the overlap areas to the adjacent pulse, superposition of grid arrangements offset in relation to one another can result.

The distance AB of the micro-zones (thus the interference period) is adjustable in the selected arrangement by the variation of the irradiation angle W between the interfering partial beams and the optical axis in the processing zone, for example, in the range between approximately 1 μm and approximately 15 μm.

The overall pulse size, thus the size of the area LP that can be irradiated using a single pulse, is also adjustable by variation of the size of the interfering partial beams in the processing zone. This can be achieved, for example, by adapting the unprocessed beam diameter or varying the focusing or the imaging scale of the optics unit used. This variation of the overall pulse size also causes a change of the intensity within the areas of constructive interference, thus the single spot energy, which can also be adjusted via the selection of the laser pulse energy.

The size of the individual micro-zones MZ, also referred to as the single spot size, is continuously adjustable with the selected arrangement from approximately 0.5 μm to approximately 3 μm. The diameter/size of the single spots changes depending on the laser energy used and depending on the irradiation angle W between the interfering partial beams and the optical axis in the processing zone.

If the edge drop of the laser intensity toward the edge of a partial beam due to a Gaussian profile is perceived to be disturbing, in some embodiments, edge areas having lower intensity can be hidden by a suitable mask.

In general, it is favorable if repeated irradiation during the transition to the next pulse is avoided to avoid an unequal distribution of the weakening of the boundary area, which is difficult to supervise. The lateral offset from pulse to pulse can however optionally also be set using a defined overlap so that single points are hit multiple times (by multiple pulses), so that the pattern of the interference processing continues over large areas. Due to the superposition, the positions at the edge of the processing zone which are initially processed with excessively low fluence can be processed with sufficient fluence overall.

In the example, an unprocessed laser beam LSR was used. If needed, homogenization of the primary laser beam can be provided.

Different surface patterns of micro-zones can be generated within the scope of the method. For example, individual pulses can be generated with spacing without overlap and then other grids with different laser power and/or different spot size and/or different spot distance can be generated in the intermediate spaces, for example, to avoid excessive energy introduction in the transition area between adjacent irradiation zones.

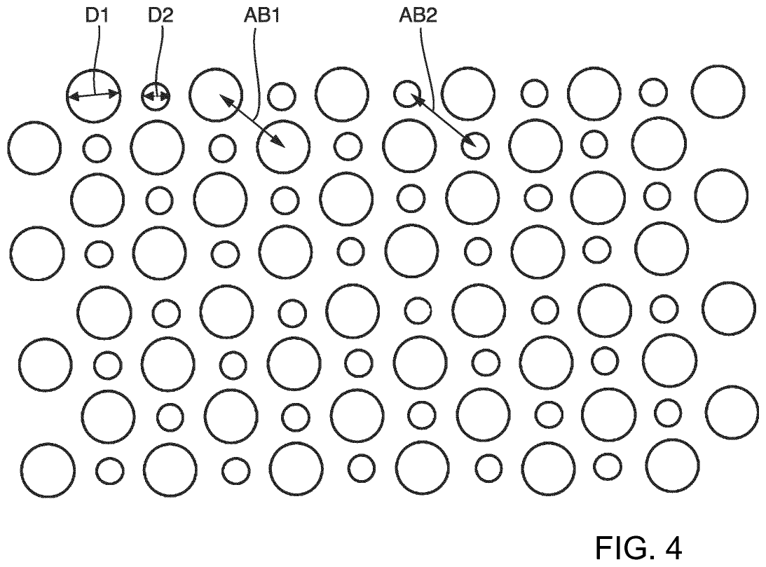

It is also possible to change the structure during the processing, for example, in a spiral shape from the outside to the inside. For example, a tighter grid can be generated in the outer area than in the inner area. Spot grids of different single spot dimensions and distances are also possible, or grids having alternating large and small effects. FIG. 4 shows an example in which micro-zones were generated in a surface area of the boundary layer in at least two processing steps performed in chronological succession. In a first processing step, a first micro-grid arrangement of first micro-zones MZ1 having first diameters D1 and first distances AB1 were generated. Then, in a following second processing step, second micro-zones MZ2 of smaller diameter D2 were generated using modified average laser power, which were distributed according to a second micro-grid arrangement having second distances AB2.

A further exemplary embodiment was designed to implement a gentle successive processing, but to implement complete processing of the entire surface at the same time.

In this case, the DLIP method was in the form of 2-beam interference to generate micro-zones in the form of lines, for example, with 5 μm line distance and 1 μm line width. The optics were aligned so that the lines extend parallel to the Y direction. The size of the irradiated surface was bounded via a mask for each of the two partial beams so that they had a size of 200 μm×200 um after imaging of these masks on the boundary surface. Edge areas of the partial beams with low fluence could thus be hidden and not reach the boundary area. The imaging was deflected line by line by a polygon scanner at a speed of 200 m/s in the X direction. For the processing, an ultrashort pulse laser having a laser pulse repetition frequency of 1 MHz was used. A pulse distance of 200 μm thus resulted and the surface was completely processed by concatenating the 200 μm sized images. In the Y direction, the sample was uniformly moved by a positioning axis so that the offset at the moment of the line change was 200 μm, so that adjacent processing zones also directly abut one another here.

The use of a method or a device for direct laser interference patterning (DLIP) for irradiating a boundary area between a growth substrate and a functional layer system for the purpose of weakening or destroying a connection between a growth substrate and a functional layer system in a laser lift-off method or LIFT method offers, in addition to the mentioned advantages, further advantages with regard to the quality of the finished product and the costs to be expended for this purpose. These advantages prove the suitability of this method for patterning planar areas in the interior of a workpiece as well, thus areas which are not located at the free surfaces of the workpiece.

The advantages result, inter alia, in that the requirements which have to be placed on the quality of the coupling of the laser radiation into the workpiece material are not as high as in conventional laser processing. As mentioned in the introduction, in some conventional methods, the rear side of the growth substrate used as the entry surface for the laser radiation has to be polished before the laser processing to avoid interfering scattering. Alternatively, smoothing of the coupling surface via an immersion technology can be provided.

In contrast thereto, if the DLIP approach is applied, sapphire wafer can possibly be used as the growth substrate immediately after being sawn off a sapphire block, without also having to polish the coupling surface beforehand. This is to be proven hereinafter on the basis of experimental data.

If DLIP is used, an additional advantage results with respect to a large tolerance of the permissible deviation of the Z position in the processing: the three or four individual beams are focused by the focusing optical unit and superimposed here in a larger area above the focal plane. In this area (also referred to as the interference volume), in which the beams overlap, the interference pattern results, which does not change in the Z direction, i.e. the XY position of the individual interference points is independent of Z. The processing position is located above the focus position and in the example shown has a diameter of approximately 250 μm. The tolerance of the Z position is in the range of a factor of 4 of this diameter. A possible wafer bow (i.e. a possible deformation of the wafer) of up to approximately 1 mm can therefore be tolerated without Z tracking in this example. The intensity of the laser radiation only changes comparatively little in this area. The high depth of field of the DLIP method can therefore be used to implement the process more cost-effectively without losses in the quality of the final product.

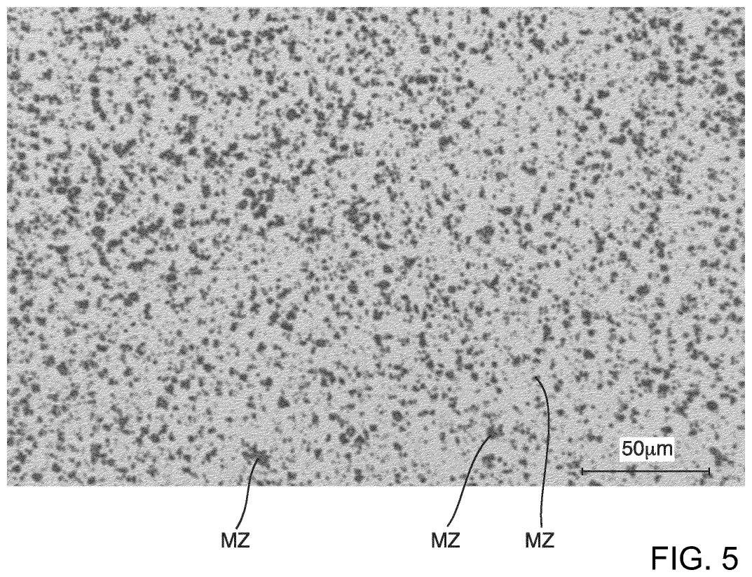

In conventional methods of laser lift-off, it has to be ensured that the coupling of the laser radiation into the growth substrate is not negatively affected excessively strongly by scattering effects, because of which the coupling surface was smoothed by polishing or the use of an immersion layer. The laser lift-off with the aid of direct laser interference patterning (DLIP), in contrast, is substantially less sensitive to scattering effects due to the roughness of the coupling surface, however. This will be explained on the basis of FIG. 5. FIG. 5 shows a microscopic picture of a DLIP patterning through an unpolished rear side of a growth substrate having a mean surface roughness of approximately Rₐ=1 μm. In this case, the processing zone no longer has the defined uniform pattern in the boundary area as in the case of coupling through a polished rear side, but rather essentially shows random patterning, in which the micro-zones MZ, which have arisen in the area having particularly high radiation intensity, have a certain size distribution within the single digit micrometer range and less and the lateral distances to directly adjacent micro-zones are also no longer uniform, but rather vary statistically over a certain distance range. This random patterning is attributed to the occurrence of speckles due to scattering of the radiation at the rough coupling surface and a substantially random superposition in the processing plane. A weakening of the boundary layer or the boundary area also results here in the entire irradiated area in such a manner that the components can then be separated from one another along the boundary area. This variant is suitable above all if a comprehensive laser lift-off is required, for example, to detach a complete layer system from a wafer.

The method and the device can be used for different applications. In some applications, for example, in the production of power LEDs, for example, for the production of light-emitting diodes for front headlights of passenger vehicles or trucks, the layer system is generally detached in a closed manner from the sapphire substrate and subsequently isolated to form the individual LEDs. In particular in such cases, it is possible to work with unpolished growth substrates.

There are also applications in which the individual functional components are already present in isolated form on the growth substrate and in which they have to be detached individually. One of these applications would be the laser lift-off of micro-LEDs for display applications. The LEDs are already isolated here and have to be detached individually, which was conventionally implemented using laser processing systems, for example, which work with excimer laser sources and use mask projection methods. These methods can be replaced by suitably designed DLIP methods and devices. Therefore, very small LEDs having, for example, square or rectangular shapes and edge lengths, for example, of 3 μm to 10 μm can be detached individually in that the areas of the LEDs are each detached by a single one or a few of the DLIP micro-zones. The micro-zones should then be arranged identically as uniformly as possible centrally on each of the micro-LEDs. This can be achieved by suitable setting of the spot sizes and distances between the spots of the micro-grid arrangement.

For the technical implementation, there are the following possibilities alternatively or additionally to those described above, among others. The combination and superposition of the partial beams can take place with the aid of a focusing element, e.g. using a lens, an objective, a focusing mirror, or an axicon. Other possibilities for generating the interference pattern can also be used, for example, with the aid of a lattice, for example, a reflection lattice. For example, lasers having pulse durations in the picosecond or nanosecond range can be used.

The use of devices and methods of DLIP in laser lift-off (LLO) or LIFT provides several advantages. Among other things, less laser power per unit of irradiated area is required for the alternating processing in the micro-range in this method than with homogeneous irradiation. Cost-effective solid-state lasers having comparatively low pulse energy, but high pulse repetition frequencies in the megahertz range can therefore be used. High laser pulse repetition frequencies enable a high throughput during the application of the method. Furthermore, parts of the layer system adjoining the boundary area are mechanically stressed less by the alternating processing in this method, so that an increasing yield in the manufacturing is to be presumed.

A further advantage of the method is that the generated pattern of micro-zones is stored as an interference pattern in the entire laser beam diameter and hundreds to thousands of micro-zones (weakening zones in micro-dimensions or nano-dimensions) can be generated using only one laser pulse within a few nanoseconds to femtoseconds in the boundary area.

The beam diameter does not have to be focused, but can even be widened depending on the required pulse energy, to nonetheless generate microscopically small structures with significantly larger processing area per laser pulse. The focusing optical unit is not used to focus each of the individual partial beams as such in the boundary area, but rather to deflect the partial beams entering parallel to one another in the direction of the targeted processing area.

A very high depth of field can be achieved in comparison to laser inscription, since DLIP does not depend on accurate focusing of the laser beam, but rather generates a spatial “interference volume” having three-dimensionally extended radiation micro-zones, within which the boundary area is similarly patterned using the corresponding interference pattern. The method is thus less sensitive to variations of the position of the workpiece in the z direction, so that more cost-effective systems can be used for the positioning in the z direction.

What is claimed is:

1. A method for producing microelectronic components, comprising a carrier and at least one microelectronic functional layer system applied to the carrier, the method comprising:
forming a functional layer system on a front side of a growth substrate;
arranging a layer-shaped carrier on a side of the functional layer system opposite to the growth substrate to form an arrangement comprising the carrier, the functional layer system, and the growth substrate;
radiating in laser radiation from a rear side of the growth substrate through the growth substrate such that the laser radiation, in a boundary area between the growth substrate and the functional layer system, weakens or destroys a connection between the growth substrate and the functional layer system in the boundary area in locally bounded areas or comprehensively;
transferring the functional layer system or parts thereof onto the carrier to form a microelectronic component,
wherein
the boundary area is irradiated by direct laser interference patterning (DLIP), wherein a laser beam emitted by a primary laser radiation source is split into at least two partial beams and the partial beams are guided so that at least two partial beams coherent with one another extend through the growth substrate and a spatial intensity pattern results in a superposition area of the coherent laser beams comprising radiation micro-zones having constructive interference and relatively high power density of the laser radiation adjacent to areas of destructive interference and low power density of the laser radiation relative to the radiation micro-zones, wherein micro-zones damaged by the laser radiation of the radiation micro-zones are generated in the boundary area, which are located in an arrangement with lateral distances to one another.

2. The method as claimed in claim 1, wherein a lateral extension of the micro-zones in at least one lateral direction is 0.5 μm to 3 μm and/or mean lateral distances of the micro-zones are of 1 μm to 15 μm and/or more than 100, or more than 1000 micro-zones are generated simultaneously in one processing step.

3. The method as claimed in claim 1, wherein the laser beam emitted by the primary laser radiation source is split into three or four partial beams.

4. The method as claimed in claims claim 1, wherein substantially punctiform or oval or approximately square or approximately rectangular micro-zones are generated, or linear micro-zones are generated.

5. The method as claimed in claim 1, wherein the micro-zones in the boundary area form a periodic micro-grid arrangement or are distributed according to a random distribution of sizes of the micro-zones and the lateral distances.

6. The method as claimed in claim 1, wherein, in a planar area of the boundary area, micro-zones are generated in at least two processing steps performed in chronological succession, wherein, in a first processing step a first grid of first micro-zones is generated and in a following second processing step second micro-zones are generated in intermediate areas between first micro-zones.

7. The method as claimed in claim 1, wherein a growth substrate having a surface roughness having a mean roughness value Ra of greater than 0.1 μm on the rear side, is used.

8. The method as claimed in claim 1, wherein a wafer separated from a material block by means of sawing is used as the growth substrate, and the laser radiation is radiated onto the rear side of the growth substrate created by sawing without an interposed lapping step and/or polishing step.

9. The method as claimed in claim 1, wherein pulsed laser radiation of a UV solid-state laser is used to irradiate the boundary area.

10. The method according to claim 1, in wherein the laser radiation is irradiated without use of a beam splitter mask such that radiation micro-zones of high power density of the laser radiation are generated in the boundary area such that micro-zones damaged by the laser radiation of the radiation micro-zones are generated in the boundary area, which are located in an arrangement having mean lateral distances in a micrometer range to one another.

11. A system that produces microelectronic components comprising a carrier and at least one microelectronic functional layer system applied to the carrier, the system comprising:
a workpiece carrier for accommodating an arrangement having a growth substrate, a functional layer system formed on a front side of the growth substrate, and a carrier, arranged on a side of the functional layer system opposite to the growth substrate;
a laser processing station for radiating laser radiation from a rear side of the growth substrate through the growth substrate such that the laser radiation is guided in a boundary area between the growth substrate and the functional layer system and a connection between the growth substrate and the functional layer system is weakened or destroyed in the boundary area,
wherein
the laser processing station comprises a laser-optical arrangement for laser patterning, in which a laser beam emitted by a primary laser radiation source can be split into at least two partial beams and the partial beams can be guided so that at least two partial beams coherent with one another extend through the growth substrate and a spatial intensity pattern is generated in a superposition area of the coherent partial beams comprising radiation micro-zones having constructive interference and relatively high power density of the laser radiation adjacent to areas of destructive interference and low power density of the laser radiation relative to the radiation micro-zones, wherein micro-zones damaged by the laser radiation of the radiation micro-zones can be generated in the boundary area, which are located in an arrangement having lateral distances to one another.

12. The system as claimed in claim 11, wherein the laser processing station is configured to irradiate the laser radiation without use of a beam splitter mask such that radiation micro-zones of high power density of the laser radiation arise in the boundary area such that micro-zones damaged by the laser radiation of the radiation micro-zones can be generated in the boundary area, which are located in an arrangement having mean lateral distances in a micrometer range to one another.

13. The system as claimed in claim 11, wherein the laser processing station comprises a workpiece movement system configured to position a workpiece to be processed in a desired processing position of the laser processing station in reaction to movement signals of a control unit, wherein the workpiece movement system comprises a first workpiece carrier movable parallel to a horizontal plane of a system coordinate system and in a vertical direction to a desired position and is rotatable around a vertical axis of rotation.

14. The system as claimed in claim 11, wherein the system is configured to perform a method for producing microelectronic components comprising a carrier and at least one microelectronic functional layer system applied to the carrier, the method comprising:
forming a functional layer system on a front side of a growth substrate;
arranging a layer-shaped carrier on a side of the functional layer system opposite to the growth substrate to form an arrangement comprising the carrier, the functional layer system, and the growth substrate;
radiating in laser radiation from a rear side of the growth substrate through the growth substrate such that the laser radiation, in a boundary area between the growth substrate and the functional layer system, weakens or destroys a connection between the growth substrate and the functional layer system in the boundary area in locally bounded areas or comprehensively;
transferring the functional layer system or parts thereof onto the carrier to form a microelectronic component,
wherein
the boundary area is irradiated by direct laser interference patterning (DLIP), wherein a laser beam emitted by a primary laser radiation source is split into at least two partial beams and the partial beams are guided so that at least two partial beams coherent with one another extend through the growth substrate and a spatial intensity pattern results in a superposition area of the coherent laser beams comprising radiation micro-zones having constructive interference and relatively high power density of the laser radiation adjacent to areas of destructive interference and low power density of the laser radiation relative to the radiation micro-zones, wherein micro-zones damaged by the laser radiation of the radiation micro-zones are generated in the boundary area. which are located in an arrangement with lateral distances to one another.

15. A device for direct laser interference patterning (DLIP) that irradiates a boundary area between a growth substrate and a functional layer system to weaken or destroy a connection between the growth substrate and the functional layer system in a laser lift-off method or a LIFT method.

16. The device as claimed in claim 15, wherein a laser beam emitted by a primary laser radiation source is split into at least two partial beams, and the partial beams are guided so that at least two partial beams coherent with one another extend through the growth substrate and a spatial intensity pattern results in a superposition area of the coherent laser beams, comprising radiation micro-zones having constructive interference and relatively high power density of the laser radiation adjacent to areas of destructive interference and low power density of the laser radiation relative to the radiation micro-zones, wherein micro-zones damaged by the laser radiation of the radiation micro-zones are generated in the boundary area, which are located in an arrangement having lateral distances to one another.
